(19) United States
(12) Patent Application Publication
(10) Pub. No.: US 2014/0265394 A1
(43) Pub. Date: Sep. 18, 2014

(54) COMPOSITE END EFFECTORS

(71) Applicant: Varian Semiconductor Equipment Associates, Inc., Gloucester, MA (US)

(72) Inventors: Paul E. Pergande, Austin, TX (US); Paul Forderhase, Austin, TX (US)

(73) Assignee: Varian Semiconductor Equipment Associates, Inc., Gloucester, MA (US)

(21) Appl. No.: 14/200,547

(22) Filed: Mar. 7, 2014

Related U.S. Application Data
(60) Provisional application No. 61/778,524, filed on Mar. 13, 2013.

(51) Int. Cl. H01L 21/677; B25J 15/00

(52) U.S. Cl. CPC H01L 21/677; B25J 15/0014
USPC 294/81.5; 156/293; 156/285

(57) ABSTRACT

An end effector includes a base, a plurality of fingers extending from the base, and a plurality of pads disposed on each of said fingers to support a substrate. The fingers comprise a carbon fiber material and taper from a first diameter and first wall thickness proximate said base to a second diameter smaller than said first diameter and second wall thickness smaller than said first wall thickness distal said base. A method includes adhering a plurality of pads along a plurality of tapered fingers, and adhering proximal ends of the plurality of tapered fingers with corresponding recesses of a base. The assembled pads, tapered fingers and base are placed on a fixture such that top surfaces of the plurality of pads rest on a top surface of the fixture and the assembly is held in place on the fixture until the adhesive has cured at room temperature.

### CROSS-REFERENCE TO RELATED APPLICATIONS

This application claims priority to pending U.S. provisional patent application Ser. No. 61/778,524, filed Mar. 13, 2013, the entirety of which application is incorporated by reference herein.

### FIELD OF THE DISCLOSURE

Embodiments of the present disclosure generally relate to the field of substrate processing, and more particularly to end effectors for use in a substrate handling systems.

### BACKGROUND OF THE DISCLOSURE

Silicon wafers are used in semiconductor or solar cell fabrication. The wafers are subjected to a multi-step manufacturing process that may involve a plurality of machines and a plurality of stations. Thus, the wafers need to be transported from one machine/station to another machine/station one or more times.

The transport of the wafers typically employs apparatuses called end effectors. A typical end effector may be hand-like in appearance where a base unit may attach to a plurality of finger-like extensions. On each of the finger-like extensions, a plurality of wafers may be seated atop wafer pads at spaced apart intervals. The end result may be a matrix of wafers supported by the plurality of end effector fingers. The end effector may typically be moved linearly (e.g., forward and backward) as well as rotationally all in the same plane (e.g., x-y axis). The end effector may also be moved in a third direction along a z-axis to provide a full range of motion.

Some end effector designs may not be able to operate at higher speeds, which limits throughput. What is needed is a new end effector design that can provide an increased throughput.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

An end effector is disclosed, comprising a base and a plurality of fingers extending from said base. The fingers may be a carbon fiber composite material. Each of the fingers may taper from a first diameter and first wall thickness proximate the base to a second diameter smaller than the first diameter and a second wall thickness smaller than the first wall thickness distal the base. A plurality of pads may be disposed on each of the fingers to support at least one substrate.

A method for making an end effector is disclosed, comprising: engaging a plurality of pads at spaced apart intervals along a plurality of tapered fingers, the plurality of pads and plurality of fingers having adhesive disposed therebetween; engaging proximal ends of the plurality of tapered fingers with corresponding recesses of a base, the plurality of fingers and the corresponding recesses having adhesive disposed therebetween; positioning the assembled pads, tapered fingers and base on a fixture such that top surfaces of the plurality of pads rest on a top surface of the fixture; and holding the assembly in place on the fixture until the adhesive has cured.

An end effector is disclosed, comprising a carbon fiber composite base having top and bottom plates and a plurality of ribs therebetween. A plurality of hollow carbon fiber composite fingers may also be included, each of the plurality of carbon fiber fingers having a proximal end and a distal end. The proximal ends may be engaged with at least one of said plurality of ribs. Each of the fingers may taper from a first diameter and a first wall thickness at the proximal end to a second diameter smaller than said first diameter and a second wall thickness smaller than said first wall thickness at the distal end. A plurality of pads may be disposed on each of the fingers to support at least one substrate.

### BRIEF DESCRIPTION OF THE DRAWINGS

By way of example, various embodiments of the disclosed device will now be described, with reference to the accompanying drawings, in which:

FIG. 1 is an isometric view of an embodiment of an exemplary end effector according to the disclosure;

FIG. 2 is a side view of the embodiment of the end effector of FIG. 1;

FIG. 3 is a cross-section view of a base of the end effector of FIG. 1, taken along line 3-3 of FIG. 1;

FIGS. 4A and 4B are isometric views of pads, and FIG. 4C is an isometric view of a pad base, for use on the end effector of FIG. 1;

FIGS. 4D and 4E are isometric and detail views, respectively, of an exemplary jig for aligning the pads of FIGS. 4A and 4B;

FIG. 5 is a top view of the embodiment of the end effector of FIG. 1 loaded with substrates;

FIG. 6 is an isometric view of an embodiment of an exemplary end effector according to the disclosure for use with a swapping robot arrangement;

FIG. 7 is an exploded view of a spar member assembly for use with the end effector of FIG. 6;

FIG. 8 is a partial isometric view of an end effector interface of the spar member assembly of FIG. 7;

FIGS. 9A-C are isometric views of an exemplary assembly fixture for use with the spar member assembly of FIG. 7;

FIG. 10 is an isometric view of the end effector of FIG. 6;

FIG. 11 is an isometric view of a tapered finger of the end effector of FIG. 6;

FIG. 12A is a cross-section view of the tapered finger of FIG. 11 taken along line 12A-12A of FIG. 11; FIGS. 12B and 12C are detail segment views of respective portions of FIG. 12A;

FIG. 13 is a cutaway view of the end effector of FIG. 6;

FIG. 14 is an isometric view of a wrist portion of the end effector of FIG. 6;

FIG. 15 is an isometric view of the end effector of FIG. 6 engaged with an assembly fixture;

FIG. 16 is a detail view of a portion of FIG. 15;

FIG. 17 is a partial cross-section view of the end effector of FIG. 6 taken along line 17-17 of FIG. 15; and

FIG. 18 is a flow chart illustrating an embodiment of the disclosed method.

### DETAILED DESCRIPTION

The end effector described herein can be used in connection with substrate handling equipment such as ion implantation systems, deposition systems, etching systems, lithography systems, vacuum systems, or other systems that process substrates. The substrates may be solar cells, semiconductor wafers, light-emitting diodes, or other wafers known to those skilled in the art. Thus, the invention is not limited to the specific embodiments described below.

End effectors may be designed to have a particular weight and stiffness capable of operation at high speeds. Acceleration of the end effector is affected by the weight of the end effector. A minimized weight can increase speed, acceleration, and overall throughput while an increased stiffness can help prevent end effector deflection or movement of the wafers transported by the end effector. The natural frequency (Fn) is the frequency at which a system naturally vibrates once it has been set into motion. In other words, Fn is the number of times a system will oscillate (move back and forth) between its original position and its displaced position if there is no outside interference. Resonance is the buildup of large vibration amplitude that occurs when an object is excited at its Fn. Undesirable mechanical resonance can cause components to break or malfunction. Fn is controlled by the ratio of stiffness to mass (k/m).

FIG. 1 is a top perspective view of an embodiment of the disclosed end effector. Composite manufacturing techniques may enable a thinner wall thickness in the fingers 103-106 with higher strength per unit mass than may be possible using isotropic homogenous materials. In one example, reinforced composite materials have a resin matrix surrounding reinforcement fibers with a high tensile modulus. For example, carbon fibers may be used as the reinforcement fibers in the fingers 103-106. These carbon fibers may have a particular volume percentage in the resin matrix, a particular modulus, or a particular orientation in the resin matrix. The resin matrix may be epoxy, a thermoset, a thermoplastic, a cyanate ester, polyester, aramid, a chlorofluorocarbon, glass, or other materials. When the resin matrix is combined with the fiber, the fiber crosslinks and hardens. This mixture of reinforcement and resin matrix is referred to as composite fiber reinforced plastic fabrication.

Fabrication using pre-impregnated material may be performed in two steps. In the first step, the resin matrix is mixed so that it is catalyzing or hardening during the combination with the fiber, which is spread from yarn to a sheet. The sheet is then stored frozen until ready for the second step. The second step is done in the final shape of the composite article and is usually done with the sheets of pre-impregnated material held by pressure or vacuum during a heated crosslinking step. The pressure or vacuum is used to eliminate voids and squeeze out excess resin matrix thus increasing the volume fraction of the fiber which improves the mechanical properties of the composite part.

The fingers 103-106 of the end effector 100 may be configured to have a relatively higher stiffness along a particular axis in order to more effectively oppose the principal loading. This higher stiffness can be achieved by changing the properties or composition of the composite materials, which in turn can increase performance as measured by the Fn. Use of carbon fibers can result in an Fn of approximately 45 to 75 hertz (Hz) and a mass of approximately 5 pounds (lbs.) to hold a 4×4 array of solar cells. Typical aluminum end effectors of similar scale and size can weigh approximately 12 lbs. and have a natural frequency of approximately 25-45 Hz.

In the illustrated embodiment, the end effector 100 is configured to hold an array of 4×4 164 millimeter (mm) solar cells, though other arrangements, sizes, or substrate types are possible. These solar cells can be held between pads 107, which may be fabricated of PEEK or other materials. The pads 107 are disposed on fingers 103-106 at spaced intervals. The fingers 103-106 can be coupled at one end to a base 101. Each pad 107 may be positioned on a pad base (not illustrated) disposed between the pad 107 and the associated finger 103-106. The illustrated embodiment includes five pads 107 on each of the fingers 103-106, though the number of pads 107 may vary based on the number of wafers that each of the fingers 103-106 is configured to support. The substrates may be disposed on one of the fingers 103-106 between an opposing pair of pads 107. The base 101 includes a wrist 102 which may be fabricated of aluminum or other materials. The wrist 102 may serve as an interface with a robot in a wafer handling system. The wrist 102 can include an aperture 110 to mate with this robot. The aperture may have pin/slot features to interface to the robot.

Four fingers 103-106 are illustrated in the end effector 100 of FIG. 1, though other numbers or configurations are possible. These fingers 103-106 are composed of a carbon fiber composite and are formed as conically-tapered tubes. Thus, the fingers 103-106 taper in both height (y-axis) and width (x-axis) from a proximal end 108 adjacent the base 101 to a distal end 109 located farther away from the base 101 (i.e., as measured along the z-axis). The fingers 103-106 may be hollow and the carbon fiber may be disposed unidirectionally along the fingers. The length profile of the fingers 103-106 may be configured to optimize the natural frequency (Fn). The stiffness of the fingers 103-106 may be maximized along the z-axis because the fingers 103-106, when in use, are subject to a load acting along the y-axis (i.e., the carried substrates) and thus are subject to bending forces applied along the y-axis.

FIG. 2 is a side view of the end effector of FIG. 1. Although the following description will proceed in relation to finger 106, it will be appreciated that the described features will apply equally to all of the fingers 103-106 of the end effector 100. As seen in FIG. 2, the fingers, such as the finger 106, have a tapered shape, such that they have a larger outer diameter “OD” adjacent the proximal end 108 and a relatively smaller OD at the distal end 109. As previously noted, the finger 106 can be hollow, and the wall thickness “T” of the finger can vary from the proximal end 108 to the distal end 109. At the proximal end 108, the finger 106 may have a maximum wall thickness “T” and a maximum OD. Both the wall thickness “T” and OD may decrease in a linear or non-linear fashion along the finger 106, reaching a minimum wall thickness “T” and a minimum OD at the distal end 109. In one non-limiting exemplary embodiment, at or adjacent to the proximal end 108 the OD may be approximately 0.875 inches (in) and the wall thickness “T” may be approximately 0.09 in. At or adjacent to the distal end 109 the OD may be approximately 0.3 in and the wall thickness “T” may be approximately 0.03 in. The variable wall thickness “T” and variable OD may be configured to be most efficient for handling a cantilevered load (i.e., the substrates), which can produce a higher Fn. In some embodiments the finger 106 may have an opening at the proximal end 108, the distal end 109 and/or along the length of the finger to allow rapid evacuation under hard vacuum conditions.

In one embodiment, the fingers 103-106 can be manufactured from carbon fiber using a process known as roll-wrapping. In another instance, the fingers 103-106 can manufactured from the carbon fiber using a process known as filament winding. Compression molding or other manufacturing processes may also be used.

In one exemplary embodiment, the fingers 103-106 can be fabricated of a reinforced material having a modulus of approximately 5 to 25 megapounds per square inch (Msi). This increases the Fn of the fingers 103-106 while minimizing the mass. During composite manufacturing, the material stiffness is configured with respect to the x, y, and z axes. The carbon fiber may have a stiffness of greater than approximately 40 Msi along the direction of its axis in one example, but the overall effective stiffness of the composite is affected by direction of the fiber selected. Selection of the fiber direction during component fabrication configures the stiffness in each direction. For example, if all the fibers are unidirectional then the component will resist force in one direction but will be comparatively soft or unable to resist force in the other two directions. In one embodiment, a preponderance or majority of fibers is configured to resist the anticipated loads and sufficient fibers are configured to resist incidental loads in other directions.

In one particular embodiment, the load on the end effector 100 is applied along the axis of the fingers 103-106 bearing the weight of the substrates. More than one unidirectional layer may be used in each component, such as 5-10 layers, using fiber having a modulus in tension of approximately 436 gigaPascals (GPa). The epoxy, however, only has a modulus of approximately 3.6 GPa. Since the fingers 103-106 are optimized for tension (i.e., to resist the bending induced by the modest inertial loads when excited to vibrate during bending around a horizontal axis normal to the direction of travel), approximately 75% of the fibers are arranged along the z-axis. The other approximately 25% of the fibers are arranged normal to the z-axis. Since approximately 45% of the material is the resin matrix, the 55% of the material made up of the fiber dominates the material stiffness of the fingers 103-106. Therefore the stiffness along the z-axis yields a Young's modulus in the direction of travel of 181 GPa. This is approximately 90% the stiffness of steel, but with a material that is roughly the density of a plastic. In another embodiment, 25% of the fibers are arranged normal to the direction of travel, which yields a Young's modulus in that direction of 61 GPa, or approximately 88% the stiffness of aluminum.

The reinforced material may have varying stiffness along the various x, y, and z axes. For example, the reinforced material may have a stiffness similar to steel along one axis, a stiffness less than steel along another axis, and a stiffness similar to epoxy along a third axis. In some embodiments the fingers 103-106 may be made of flame resistant materials. For example the fingers 103-106 may be made from a material that is UL94V-0 rated.

In some embodiments the fingers 103-106 do not include holes for attaching the pads 107. That is, the pads 107 are not fixed to the fingers 103-106 using fasteners. Instead, the pads 107 may be attached to the fingers 103-106 using and adhesive such as epoxy, or an epoxy modified with a thickener. This may simplify assembly and reduce cost, though fasteners or other fastening mechanisms can be used. In one embodiment the pads 107 may be removably attached to the fingers 103-106, though the pads 107 also may be permanently attached to the fingers. The adhesive used to bond the pads 107 to the fingers 103-106 may include a thickening agent such as fumed silica. By adding a thickening agent, the viscosity of the adhesive can be reduces so that it does not run out of the spaces between the pads 107 and the fingers 103-106 prior to setting. A more gelatinous adhesive may also enable a looser tolerance between the pads 107 and fingers 103-106, because the epoxy can help fill any gaps during alignment of the pieces. In some embodiments the pads 107 can be replaceable.

As will be appreciated, it can be important that the end effector 100 exhibit a high degree of flatness so that even engagement and precise placement of the substrates is assured during use. During assembly, the fingers 103-106 and pads 107 can be positioned on a fixture such that the top surfaces 111 of the pads engage the fixture (i.e., the fingers and pads are upside down with respect to their position during use). This arrangement can ensure that a desired flatness of the pads 107 with respect to each other and to the datum surfaces on the wrist 102 is achieved during the assembly and bonding process. In some embodiments the components of the end effector 100 are placed in this fixture in a relatively stress-free condition (i.e., compression or extension of the components in the end effector 100 may be avoided) so that they can maintain the desired flatness after the epoxy cures. The components (base 101, wrist 102, fingers 103-106, pads 107) can then be bonded together with adhesive, which is then allowed to set. Using this technique, final alignment and flatness of the end effector 100 is imparted by the fixture, against which the top surfaces 111 of the pads 107 sit. This unitary alignment approach can provide final alignment or flatness of the components of the end effector 100 that is tighter than can be achieved than by separately flatness of the individual components. Desirably, the top surfaces of the pads 107 of the completed end effector 100 will all lie in substantially the same plane.

To facilitate the aforementioned process, the various components of the end effector 100, such as the fingers 103-106, the base 101, the wrist 102, and pads 107 may be dimensioned so that they do not fit tightly together in the un-bonded condition. Rather, the components may be sized so as to have predefined bond gaps between respective engagement surfaces. As such, when the components are fit together they can “settle” against each other and against the flat surface of the fixture. The adhesive fills the bond gaps “BG” (see FIG. 17) between the components and cures with the components in the “settled” condition (i.e., with the top surfaces 111 of the pads 107 all flatly aligned with each other against the flat surface of the fixture.) This technique can result in relatively stress-free bonding of the components, which results in an end effector 100 that is substantially flat. In some embodiments the end effector 100 has a flatness of 0.01 in. over a 39 in. length.

Assembly in the fixture may be performed at room temperature, and curing of the adhesive may also occur at room temperature. This avoids relative growth or contraction between components, as can occur with prior hot curing methods of adhesive bonding. The adhesive may be selected such that it achieves a desired degree of crosslinking at room temperature to provide joints having strengths sufficient to maintain the components of the end effector 100 fixed together during long term operation.

FIG. 3 shows an exemplary structural embodiment of the base 101 of the end effector 100. In the illustrated embodiment, the base 101 includes a carbon composite core 113 bonded to carbon fiber plates 115, 117 on the top and bottom surfaces. In alternative embodiments the base 101 could be fabricated from carbon fiber plates 115, 117 bonded to a core of magnesium, titanium, stamped steel or other materials. In the illustrated embodiment the base 101 is reinforced with a plurality of ribs 119, which provide stiffness along one or more axes. In one instance, pairs of ribs 119 are bonded together to provide openings therebetween having a hexagon shape 121. Some openings between the ribs may have a curved shape 123 to accommodate one or more of fingers 103-106 (FIGS. 1 and 2) to be inserted therein during assembly of the components of the end effector 100.

The geometry of components in the base 101 can be configured to maximize its stiffness and minimize its mass. For example, the orientation of the high-modulus reinforcement fibers of components in the base 101 may be configured to maximize this stiffness. Many fibers in the components can be unidirectional, but some fibers may be added with different orientations to brace the component against incidental loads and to allow handling of the component. In some embodiments a majority of fibers may be oriented to resist the principal load while a minimum proportion of fibers may be oriented at other angles. In one embodiment, the plates 300, 301 can be trimmed from a larger carbon fiber sheet using, for example, a water jet cutter, a band saw, or a wire saw.

FIGS. 4A and 4B are perspective views of exemplary embodiments of a pad 107 for use with the end effector 100. As noted, in some embodiments the pad 107 may be directly coupled to one of the fingers 103-106 using adhesive, fitted parts, fasteners, or a combination thereof. Alternatively, the pad 107 can be removably mounted on a pad base 401 which itself is fixed to the fingers 103-106. Such an arrangement can reduce the amount of time needed to replace the pads 107 when they become worn.

The pad base 401 may have a saddle portion 403 (FIG. 4C), one or more oppositely disposed pad engaging portions 405, and a central alignment portion 407 disposed above the saddle portion. The saddle portion 403 may be curved to encompass, cover, or connect to at least some of the outer radius of the associated finger 103-106. One or more pads 107 can be removably fastened to respective pad engaging portions 405 of the pad base 401, as shown in FIGS. 4A and 4B. In the illustrated embodiment the pad engaging portions 405 and the pads 107 have correspondingly aligned fastener holes 1405 (FIG. 4D) and 1107 so that a fastener such as a screw can be used to fix them together.

The pads 107 can have a main portion 107a that includes the fastener hole 1107 and a pair of recessed portions 107b attached to opposite sides of the main portion 107a. In use, a substrate can rest on the recessed portions 107b such that a side of the substrate engages the main portion 107a of each pad 107. Each recessed portion 107b may include a cushion 107c coupled to each recessed portion 107b. The cushion 107c may be silicone, PEEK, or other appropriate material, selected to control the coefficient of friction between the substrate and the end effector 100. The cushion 107c may extend above the associated recessed portion 107b to engage the substrate. As can be seen, the sides of the main portion 107a can be curved to help align substrates on the recessed portions 107b. Alternatively, the sides of the main portion can be flat.

FIGS. 4D and 4E show an arrangement in which separate fence elements 107d are positioned on the main portion 107a of each pad 107. Thus, with this embodiment, the separate fence elements 107d can be used to align the substrates on the recessed portions 107b of the pads 107. Also shown in FIGS. 4D and 4E is an exemplary alignment jig 600 for use in aligning the fence elements 107d. The jig 600 includes a plurality of openings 602 that correspond to the position of the pads 107 and fence elements 107d on the fingers 103-106. A first edge 604 bounding each opening 602 may be oriented perpendicular to the axes of the fingers 103-106, and may be aligned with respective side edges 107e of the fence elements 107d associated with a particular pad 107. As can be seen, the side edges 107e of the fences 107d can have a convex curvature so that each fence element engages an associated substrate along a tangent of the convex curvature. Aligning the side edges 107e of the fence elements 107d with the first edge 604 of the jig 600 ensures the fence elements 107d are parallel, thus ensuring a desired contact and alignment with the associated substrate will occur. The disclosed jig 600 may be used to align multiple sets of fence elements 107d at once. It will be appreciated that the alignment jig 600 can be employed in the same or similar manner to align the main portions 107a where the pad embodiment shown in FIGS. 4A and 4B is used.

In the illustrated embodiment, the cushions 107d are fixed to the top surface 107c of the associated pad 107 using the same fastener that is used to fix the pad to the saddle portion 403.

At least one of the pads 107, or the pad base 401, can include one or more alignment features for aligning the end effector 100 to a substrate handling system. In the illustrated embodiment, the alignment features comprise recesses 1400 formed in the central alignment portion 407 of the pad base 401. The pad base 401 associated with one finger 103 comprises a round opening, while the pad base 401 associated with another finger 106 comprises a slot. To align the end effector 100 to the substrate handling system (not show), a jig is provided having two pins that engage the hole/slot features 1400 of each end effector pair in the system. When the pair of end effectors are correctly positioned, the system software is “taught” those positions so the substrate handling robots can repeatably hand off substrates between the various end effectors in the substrate handling system.

Although the illustrated embodiment shows a pad base 401 having a pair of pads 107 mounted thereon, it will be appreciated that other arrangements can also be used. For example, a single pad 107 can be used with a single pad base 401. Alternatively, the pad 107 and pad base 401 can be a single piece.

In addition, the pad 107 can be coupled to the pad base 401 using mechanical fastening techniques other than screws. For example, mechanical interlocking features may be used.

FIG. 5 is a top view of the end effector 100 illustrated in FIG. 1 loaded with a plurality of substrates 500. In the illustrated embodiment, the end effector 100 is holding sixteen (16) solar cells 500 in a 4×4 array. Each solar cell 500 is positioned on a finger 103-106 between an adjacent pair of pads 107. If the substrate is positioned on one of the fingers 103-106 against a pad 107, there may be a gap between that substrate and the main portion, such as the pad base 401 of FIGS. 4A and 4B, in the opposing pad 107. The fingers 103-106 may have a length (in the z-axis) such that the pads 107 closest to the distal end 109 are positioned at the end of the fingers 103-106. Thus, the fingers 103-106 may not extend beyond the pads 107.

Referring now to FIG. 6 an embodiment of an end effector 200 according to the disclosure is shown. The disclosed end effector 200 can have an increased natural frequency (Fn) ˜73 Hz as compared to end effectors made from traditional materials. The disclosed end effector 200 can also have half the mass compared to end effectors made from traditional materials. This enables the end effector to undergo gentler acceleration to achieve the same system substrate throughput as current systems. The disclosed arrangement allows the associated processing tool to run for longer periods without operator intervention or machine downtime. The end effector 200 may include some or all of the features described in relation to the end effector 100 of FIGS. 1-5.

In the illustrated embodiment, the end effector 200 is configured for use in a swap robot application, though it will be appreciated that its use is not so limited. The end effector can be coupled to a proximal portion 303 of the spar member 300 via an end effector interface 302. A distal portion 304 of the spar member 300 is coupled to a hub 305, which itself is coupled to a robot actuator interface (not shown) which is coupled to a robot.

As shown in FIG. 7, the spar member 300 is a tube member made from carbon fiber composite material, and is a constant diameter, constant wall thickness tube member. As previously noted, the use of composite manufacturing techniques enable a thinner typical wall and a higher strength per unit mass than is possible using metals and other traditional materials. The reinforced composite materials used for the spar member 300 and end effector 200 can include a resin matrix surrounding reinforcement fibers that have an extremely high tensile modulus. The composite material has mechanical properties that are related to the matrix and reinforcement properties depending on the direction of consideration. The use of composite materials with carbon fiber as the reinforcement allows the material stiffness to be tailored to the load. By configuring the material in the end effector to have a high stiffness opposing the principal loading direction, design performance can be enhanced, as measured by natural frequency. Although the design is shown for use with a 4×4 array of solar cells, it is envisioned that the design can find application in any robot end effector, and more broadly, for any high-performance part that must be of limited mass against a specified load.

Like the spar member 300, the end effector 200 may be made from carbon fiber composite materials. The hub 305 and end effector interface 302 may be metal (e.g., aluminum) or other suitable material. The spar member 300 may be bonded to the hub 305 and the end effector interface 302 using a suitable adhesive, such as an epoxy.

Where epoxy is used as the adhesive it can generally consist of fully reactive A and B components which react to form extremely an extremely high molecular weight matrix. This final form is substantially free of solvents or other low molecular weight components that would be mobilized in the presence of vacuum. This high molecular weight final product makes epoxies valuable in the use of automated robotic delivery systems that see service in vacuum as components made of an epoxy matrix do not outgas.

FIG. 8 shows the end effector interface 302 in more detail. The end effector interface 302 has a first side 308 for engaging the spar member 300 and a second side 310 for engaging the end effector 200. The first side 308 may therefore have a curved shape that conforms to the curved outer surface of the spar member 300. The second side 310 may have a plurality of clearance cuts 312 that form protrusions 313 that locate and fit to corresponding features of the end effector 200. This can improve machined part yield and can clearly define where the two pieces are mated together, resulting in a well-defined parallel bolted joint when the assembly is installed. The end effector interface 302 includes a central opening 314 in the second side 310 that receives a pin 315. The pin also mates with the end effector 200 enabling the end effector to be rotated about the pin axis to facilitate system alignment.

FIGS. 9A-C show an exemplary assembly fixture 400 for aligning the spar member 300, hub 305 and end effector interface 302 during bonding, and for controlling the flatness and perpendicularity of the hub mounting plane and the end effector interface. The assembly fixture 400 includes a vertically oriented hub-engaging portion 402 for engaging a pair of hubs 305, and a horizontally oriented interface engaging portion 404 for engaging a pair of end effector interfaces 302. Two sets of vertical pins 406 extend from the interface engaging portion 402 for bearing against the second sides 310 (FIG. 8) of a pair of end effector interfaces 302. The assembly fixture 400 can be a highly flat, highly toleranced granite fixture capable of imparting a desired high degree of alignment to the spar member 300, end effector interface 302 and hub 305 during bonding. Although not visible in this view, bond gaps are formed between corresponding surfaces of the components. These bond gaps enable the components to fit together, and to settle against the assembly fixture, with little or no imposed stress (i.e., the parts are fixtured in a manner that does not compress or extend any of them, since such compression or extension would subsequently release when the assembly is demolded, causing an excursion from the desired planarity or dimension). During bonding, the adhesive fills the bond gaps so that the final bonded assembly assumes the highly toleranced configuration of the assembly fixture.

In one embodiment, bonding is performed at room temperature to minimize or eliminate the effects of differential expansion/contraction of the components. The resulting assembly can have a high degree of perpendicularity (e.g. 0.002 in.) between the hub 305 and end effector interface 302. Owing to the room temperature cure, the low stress assembly, and the highly tolerance assembly fixture 400, a tightly toleranced resulting assembly can be achieved even though the individual components (spar member 300, end effector interface 302, and hub 305) may have relatively looser tolerances themselves.

FIG. 10 shows the end effector 200, which includes a base 201, a plurality of fingers 203-206 and a plurality of pads disposed along each of the plurality of fingers. In this view, the pad bases 401 are visible, as the pads themselves have not yet been assembled. The pad bases 401 (and pads 207) may have some or all of the features of the pads 107 discussed in relation to the embodiment of FIGS. 1-5, and thus those features will not be repeated here. In addition, the pads 207 may include separate or integral fence elements similar to the fence elements 107d described in relation to the embodiments of FIGS. 1-5.

As shown in FIGS. 11 and 12, the fingers 203-206 comprise carbon fiber composite tapered conical tubes, which may be the same or similar to the fingers 103-106 described in relation to FIGS. 1-5. The tube diameter and length profile may be optimized to maximize natural frequency, yet also contain all of the features found on existing end effectors. Since the fingers 203-206 are subjected to a bending load during operation, it can be advantageous to maximize the stiffness of the fingers along their longitudinal axes to maximize the stiffness of the fingers so that they can resist bending when subjected to the loads associated with carried substrates.

The fingers 203-206 may be made from a unidirectional carbon fiber material. The fingers 203-206 may comprise tubular elements having a variable wall thickness and a varying diameter. As shown in FIGS. 11 and 12A-12C, the fingers 203-206 have a tapered shape, such that they have a larger outer diameter “OD” adjacent the proximal end 208 (where they are bonded to the base 201) and a relatively smaller OD at the distal end 209. The fingers 203-206 may have a circular shape in cross-section. As previously noted, the fingers 203-206 can be hollow, and the wall thickness “T” of the fingers can vary from the proximal end 208 to the distal end 209. Thus, at the proximal end 208, the fingers 203-206 may have a maximum wall thickness “T” and a maximum OD. Both the wall thickness “T” and OD may decrease in a linear or non-linear fashion along the finger 203-206, reaching a minimum wall thickness “T” and a minimum OD at the distal end 209. This variable wall, variable diameter distribution of material is the most efficient possible for a cantilever load, producing the highest natural frequency. The variable diameter variable thickness is fabricated with a composite manufacturing process known as roll-wrapping. This shape can also be attained by using another composite manufacturing process called filament winding. In one embodiment, the carbon fiber composite materials are UL94V-0 rated.

In some embodiments the fingers 203-206 may be made from a reinforced material having a reinforcement material with a Young's modulus of ˜5-25 Msi to increase the natural frequency of the finger while minimizing a desired mass. During composite manufacturing, it is desirable to configure the material stiffness with respect to each of the three orthogonal axes. While the fiber itself may have a stiffness upwards of 40 Msi, the effective stiffness of the composite obeys the constitutive equations for the rule of volumes. Thus, the material can be configured to have a stiffness similar to steel along one of three axes, with the second axis having a stiffness less than steel, and the third, approximately that of the epoxy matrix.

FIG. 13 is a cutaway view of the base 201 showing the composite core 213 bonded to a carbon fiber bottom plate 215. The carbon fiber top plate is not shown. The composite core base geometry is optimized to maximize stiffness and minimize mass. The composite parts in the base are optimized by selecting the orientation of the high-modulus reinforcement fibers. An adhesive matrix is added (and which hardens) to transmit the load between mounting surfaces to the reinforcement fibers. A minority of fibers can also added to brace the part against incidental loads and to allow handling. An optimized part has most of the fibers to oriented resist the principal load with a minimum proportion of fibers oriented at other angles.

The composite core 213 may be reinforced with ribs 217 having a linear shape, and adjacent edges between components are visible throughout the length of the base 201. This linear construction provides stiffness along the axis of the blade and provides visibility along the entire length of the epoxy joint, providing an easy means of visibly checking the distribution of adhesive between the components after bonding.

As shown in FIG. 13, the base 201 includes a wrist plate 219 engaged with the composite core 213 and a carbon fiber top plate and a carbon fiber bottom plate 215. The wrist plate 219, shown in detail in FIG. 14, may also include features that enable it to interface with the end effector interface 302. For example, a first side 221 of the wrist plate 219 may have a plurality of protrusions (not shown) configured to engage protrusions 313 formed by the plurality of clearance cuts 312 on the end effector interface (FIG. 8) to align the base 201 with the spar member 300. A second side 223 of the wrist plate 219 may include a plurality of first and second sets of projections 224, 226. The first set of projections 224 may be positioned, sized and configured to be received within the proximal ends of the fingers 203-206 with which they are associated as best seen in FIG. 13.) The second set of projections 226 may be disposed between ones of the first set of projections 224 and may be positioned, sized and configured to mate with the ribs 217 of the composite core 213.

Referring now to FIGS. 15 and 16, a technique will be described for assembling and bonding the components of the end effector 200. All of the components of the end effector 200 may be provisionally assembled on a highly flat, highly toleranced assembly fixture 500. The assembly fixture 500 may be a structure having a high degree of flatness, such as a granite block. The fingers 203-206 and pad bases 401 may be laid out on the fixture 500 in an upside down configuration (i.e., so that the top surfaces 411 (see FIG. 10) of the pad bases are resting on a top surface 502 of the fixture). This arrangement ensures that when all of the components are bonded together, the pad bases 401 (and thus the pads 207 that will engage thereto) will have the same degree of planarity that the top surface 502 of the fixture (i.e., they will be located in substantially the same plane).

In some embodiments, the pad bases 401 may be clamped to the top surface 502 of the fixture to ensure consistent engagement occurs between the two during the curing process. In some embodiments this clamping is achieved by mechanical clamps. In other embodiments this clamping can be achieved using a vacuum. For example, vacuum ports can be fabricated into the assembly fixture 500 directly beneath the pads 207. Once the pad bases 401 and fingers have been fit together, a vacuum pump coupled to the vacuum ports can draw air through the ports, clamping the pad bases 401 in place on the assembly fixture 502. The vacuum clamping arrangement is desirable as it places less stress on the pad bases 401 during the curing process, leading ultimately to a flatter end effector 200. It will be appreciated that this assembly technique is equally applicable for assembling the end effector 100 of FIGS. 1-5.

As with the embodiment described in relation to FIGS. 1-5, it is desirable to place all of the components of the end effector 200 in the assembly fixture 500 in a stress-free condition, bonded together with adhesive, and allowed to set. Doing so enables parts to be produced with a high degree of flatness (e.g. 0.010 inches over 3 feet). This degree of perpendicularity is desirable for use in high-speed automated media handling and placement systems for semiconductor or solar cell manufacturing, and rivals the flatness obtainable through the best subtractive manufacturing techniques.

In some embodiments the various individual components of the end effector 200 may be dimensioned so that they do not fit tightly together in the un-bonded condition. Rather, the components may be sized so as to have predefined bond gaps “BG,” between respective engagement surfaces, examples of which can be seen in FIG. 17. As such, when the components are fit together they can “settle” against each other and against the flat surface of the fixture. The adhesive fills the bond gaps “BG” between components and cures with the components in the “settled” condition (i.e., with the top surfaces 211 of the pad bases 401 all flatly aligned with each other against the flat top surface 502 of the fixture 500.) This technique can result in relatively stress-free bonding of the components, which results in an end effector 200 that is substantially flat.

The adhesive used to bond the components of the end effector 200 has a thickening agent such as fumed silica (one trade name being cab-o-sil). This thickening agent increases the viscosity of the adhesive used to bond the pads so that the adhesive does not run out of the bond gaps “BG” prior to crosslinking (setting). The use of a gelatinous adhesive in this application allows for a looser tolerance between components, and enables the production of parts with high flatness. Adhesive thus thickened stays in the position between parts when placed by any reasonable dispensing method. This gel fills the bond gap “BG” deliberately left in the design between adjacent parts (see FIG. 17). As previously noted, the bond gap allows the erasure of individual part tolerances in the overall assembly, enabling the high flatness. Alternately a thixotropic agent being prepared with sufficient viscosity may be used for bonding, e.g. Hysol Loctite 0151.

Assembly of the components in the fixture 500 may be performed at room temperature, and curing of the adhesive may also occur at room temperature. This avoids relative growth or contraction between components, as can occur with prior hot curing methods of adhesive bonding. The adhesive may be selected such that it achieves a desired degree of crosslinking at room temperature to provide joints having strengths sufficient to maintain the components of the end effector 200 fixed together during long term operation.

Referring now to FIG. 18, an exemplary method according to the disclosure will be described. At step 1000, a plurality of pads are engaged at spaced apart intervals along a plurality of tapered fingers. The plurality of pads and plurality of fingers have adhesive disposed therebetween. At step 1100, proximal ends of the plurality of tapered fingers are engaged with corresponding recesses of a base. The plurality of fingers and the corresponding recesses have adhesive disposed therebetween. In some embodiments, the adhesive is an epoxy. At step 1200, the assembled pads, tapered fingers and base are positioned on a fixture such that top surfaces of the plurality of pads rest on a top surface of the fixture. In some embodiments, the adhesive is an epoxy. At step 1300, the assembly is held in place on the fixture until the adhesive has cured. In some embodiments the assembly is held in place on the fixture at room temperature until the adhesive has cured.

The inventors have discovered that high planarity, which is desirable in the design of automated robotic substrate handling systems can be achieved if final assembly of components is performed at room temperature, and that the adhesive being used in the final assembly is allowed to completely cure at room temperature to avoid any growth or contraction between adjacent components of dissimilar materials. This is contrary to common practice in the composite fabrication industry which employs oven-curing of composite parts to allow a full crosslinking of the adhesive. With the disclosed process, adhesives are used that crosslink sufficiently at room temperature to provide a structural joint having a desired strength and longevity. Reduced mechanical properties (as compared to oven curing processes) are accepted in exchange for the high planarity and dimensional tolerances attainable with the disclosed room-temperature assembly and curing technique. This method only serves to reduce overall costs of the assembly as compared to traditional composite oven-curing practices that require a post-machining step to attain the same high planarity or part tolerance.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. These other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein. As used herein, an element or step recited in the singular and proceeded with the word “a” or “an” should be understood as not excluding plural elements or steps, unless such exclusion is explicitly recited. Furthermore, references to “one embodiment” of the present disclosure are not intended to be interpreted as excluding the existence of additional embodiments that also incorporate the recited features.

1. An end effector comprising:
a base;
a plurality of fingers extending from said base, said fingers comprising a carbon fiber material, each of said fingers tapering from a first diameter and first wall thickness proximate said base to a second diameter smaller than said first diameter and second wall thickness smaller than said first wall thickness distal said base; and
a plurality of pads disposed on each of said fingers to support at least one substrate.

2. The end effector of claim 1, wherein each of said fingers has a circular cross section.

3. The end effector of claim 1, wherein each of said fingers is hollow.

4. The end effector of claim 1, wherein said base comprises top and bottom plates positioned opposite one another and a plurality of ribs disposed between the top and bottom plates.

5. The end effector of claim 4, wherein the top and bottom plates comprise carbon fiber material.

6. The end effector of claim 1, each of said fingers tapering along an entirety of a length of each of said fingers.

7. The end effector of claim 1, further comprising a wrist plate coupled to one end of the base, the wrist plate having a plurality of first protrusions for engaging the fingers and a plurality of second protrusions for engaging a plurality of ribs within the base.

8. The end effector of claim 1, further comprising a spar member, a hub and an end effector interface, the end effector interface coupled between the spar member and base, the spar member coupled to the hub, wherein the spar member comprises a carbon fiber composite.

9. The end effector of claim 8, wherein the end effector interface has a plurality of protrusions configured to engage protrusions in the base to fix a position of the base with respect to the spar member.

10. A method for making an end effector, comprising:
engaging a plurality of pads at spaced apart intervals along a plurality of tapered fingers, the plurality of pads and plurality of fingers having adhesive disposed therebetween;
engaging proximal ends of the plurality of tapered fingers with corresponding recesses of a base, the plurality of fingers and the corresponding recesses having adhesive disposed therebetween;
positioning the plurality of pads, the plurality of tapered fingers and the base on a fixture such that top surfaces of the plurality of pads contact a top surface of the fixture; and
holding the plurality of pads, the plurality of tapered fingers and the base in place on the fixture until the adhesive has cured.

11. The method of claim 10, wherein the adhesive is an epoxy.

12. The method of claim 11, wherein the epoxy includes a thickening agent.

13. The method of claim 10, wherein the each of the plurality of pads forms a predefined bond gap with an outer surface of each of the plurality of tapered fingers, at least some of the predefined bond gaps filled with the adhesive.

14. The method of claim 10, wherein each of the plurality of tapered fingers forms a predefined bond gap with the recesses of the base, at least some of the predefined bond gaps filled with the adhesive.

15. The method of claim 10, wherein holding the plurality of pads, the plurality of tapered fingers and the base in place on the fixture until the adhesive has cured allows the plurality of pads, the plurality of tapered fingers and the base to settle with respect to each other so that when the adhesive has cured the top surfaces of the plurality of pads are aligned in a same plane.

16. The method of claim 10, wherein holding the plurality of pads, the plurality of tapered fingers and the base in place on the fixture until the adhesive has cured is performed at room temperature.

17. The method of claim 10, wherein holding the plurality of pads, the plurality of tapered fingers and the base in place on the fixture until the adhesive has cured is performed without applying external clamping force to hold the plurality of pads, the plurality of tapered fingers and the base together.

18. The method of claim 10, wherein holding the plurality of pads, the plurality of tapered fingers and the base in place on the fixture until the adhesive has cured includes applying a vacuum to the top surfaces of the plurality of pads via vacuum ports formed in the fixture.

19. An end effector comprising:
a carbon fiber composite base comprising top and bottom plates and a plurality of ribs disposed therebetween;
a plurality of hollow carbon fiber composite fingers, each of the plurality of carbon fiber fingers having a proximal end and a distal end, the proximal end of each of the plurality of carbon fiber fingers engaged with at least one of said plurality of ribs, each of said fingers tapering from a first diameter and a first wall thickness at said proximal end to a second diameter smaller than said first diameter and a second wall thickness smaller than said first wall thickness at said distal end; and
a plurality of pads disposed on each of said fingers to support at least one substrate.

20. The end effector of claim 19, further comprising a spar member, a hub and an end effector interface, the end effector interface coupled between the spar member and base, the spar member coupled to the hub, wherein the spar member comprises a carbon fiber composite.
